(19) United States
(12) Patent Application Publication
(10) Pub. No.: US 2025/0112200 A1
(43) Pub. Date: Apr. 3, 2025

(54) HYBRID BONDING OF THIN DIE STRUCTURES BY SELF-ALIGNMENT ASSISTED ASSEMBLY

(71) Applicant: Intel Corporation, Santa Clara, CA (US)

(72) Inventors: Adel Elsherbini, Chandler, AZ (US); Kimin Jun, Portland, OR (US); Feras Eid, Chandler, AZ (US); Thomas Sounart, Chandler, AZ (US); Yi Shi, Chandler, AZ (US); Shawna Liff, Scottsdale, AZ (US); Johanna Swan, Scottsdale, AZ (US); Michael Baker, Gilbert, AZ (US); Bhaskar Jyoti Krishnatreya, Hillsboro, OR (US); Chien-An Chen, San Jose, CA (US)

(73) Assignee: Intel Corporation, Santa Clara, CA (US)

(21) Appl. No.: 18/374,559

(22) Filed: Sep. 28, 2023

(51) Int. Cl. H01L 23/00; H01L 21/56; H01L 23/31; H01L 23/498; H01L 25/065

(52) U.S. Cl. CPC H01L 24/80; H01L 21/56; H01L 23/3128; H01L 23/49816; H01L 24/08; H01L 25/0655; H01L 2224/08225; H01L 2224/80143; H01L 2224/80895; H01L 2224/80896

(57) ABSTRACT

A surface of an integrated circuit (IC) die structure and a substrate to which the IC die structure is to be bonded include biphilic regions suitable for liquid droplet formation and droplet-based fine alignment of the IC die structure to the substrate. To ensure warpage of the IC die structure does not interfere with droplet-based fine alignment process, an IC die structure of greater thickness is aligned to the substrate and thickness of the IC die structure subsequently reduced. In some embodiments, a back side of the IC die structure is polished back post attachment. In some alternative embodiments, the IC die structure includes sacrificial die-level carrier is removed after fine alignment and/or bonding.

### BACKGROUND

Integrated circuit (IC) die can be assembled with solder attachment techniques where solder features are brought into contact to join dies to a host or base substrate. However, solder assembly techniques are difficult to scale below solder-bonded feature pitches that are in the tens of microns (e.g., 10-25 μm).

IC die may instead be assembled with hybrid bonding techniques where metallic bond sites of an IC die are directly interdiffused with corresponding metallic bond sites of a host or base substrate. Such bonding is referred to as “hybrid” because a bond also forms between dielectric materials adjacent to the metallic bond sites. During a hybrid bonding process, components (e.g., dies) having corresponding bond sites, are brought together to interface with one another. At room temperature, dielectric material adheres sufficiently to establish an initial bond (e.g., due to Van der Waals forces). A thermal anneal may then fuse complementary metallic bond sites, and also increase the strength of the dielectric material bond interface. Hybrid bonding techniques are scalable well below bonded feature pitches of 1 μm. However, such nanometer pitch assembly techniques rely on nanometer scale (e.g., <500 nm) fine alignment of IC die to the base substrate, which can be time consuming and/or expensive to implement.

Techniques and architectures for hybrid bonding at nanometer scales in high volume manufacturing are therefore commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating self-alignment assisted assembly (SA3) methods for thin integrated circuit (IC) die structures, in accordance with some embodiments;

FIG. 2A is a cross-sectional view of a wafer or panel comprising a plurality of base substrate structures, each base substrate structure comprising a biphilic surface structure, in accordance with some embodiments;

FIG. 2B is a plan view of the base component wafer or panel illustrated in FIG. 2A, in accordance with some embodiments;

FIG. 3A is a cross-sectional view of thick IC die structures being coarse aligned and placed on liquid droplets confined in bonding regions, in accordance with some embodiments;

FIG. 3B is a plan view of aligning and placing the thick IC die structures of FIG. 3A, in accordance with some embodiments;

FIG. 4A is a cross-sectional view of a composite structure comprising thick IC die structures hybrid bonded to bonding regions of biphilic structures, in accordance with some embodiments;

FIG. 4B is a plan view of the composite structure shown in FIG. 4A, in accordance with some embodiments;

FIG. 5A is a cross-sectional view of a composite structure comprising thick IC die structures and a dielectric material therebetween, in accordance with some embodiments;

FIG. 5B is a plan view of the composite structure illustrated in FIG. 5A, in accordance with some embodiments;

FIG. 6A is a cross-sectional view depicting a thinning of hybrid-bonded composite structures, in accordance with some embodiments;

FIG. 6B is a plan view of the thinning of hybrid-bonded composite structures, in accordance with some embodiments;

FIG. 7A is a cross-sectional view of a composite structure dielectric material between and over the bonded thin IC die structures, in accordance with some embodiments;

FIG. 7B is a plan view of a composite structure dielectric material between and over the bonded thin IC die structures, in accordance with some embodiments;

FIG. 8 is a flow diagram illustrating self-alignment assisted assembly (SA3) methods for thin integrated circuit (IC) die structures, in accordance with some alternative embodiments;

FIG. 9 is a cross-sectional view of a wafer comprising a plurality of IC die, each IC die comprising a biphilic surface structure, in accordance with some embodiments;

FIG. 10 is a cross-sectional view of an assembly comprising IC die affixed to a frontside carrier, in accordance with some embodiments;

FIG. 11 is a cross-sectional view of IC die affixed to a backside carrier, in accordance with some embodiments;

FIG. 12 is a cross-sectional view of singulated thick IC die structures, each comprising a die-level backside carrier, in accordance with some embodiments;

FIG. 13 is a cross-sectional view of singulated thick IC die structures being coarse aligned and placed on liquid droplets confined to bonding regions, in accordance with some embodiments;

FIG. 14 is a cross-sectional view of a composite structure comprising thick IC die structures hybrid bonded to a base substrate structure, in accordance with some embodiments;

FIG. 15 is a cross-sectional view of a composite structure comprising thin IC die structures following removal of die-level carriers, in accordance with some embodiments;

FIG. 16 is a cross-sectional view of a composite structure comprising dielectric material over thin IC die structures, in accordance with some embodiments;

FIG. 17 is a cross-sectional view of system comprising a heat sink and a host component assembled with a hybrid bonded composite structure further comprising a thin IC die structure, in accordance with some embodiments;

FIG. 18 illustrates a mobile computing platform and a data server machine employing a multi-chip package, in accordance with some embodiments; and

FIG. 19 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As previously noted, hybrid bonding techniques offer advantages in the assembly of IC die structures to other IC die structures or some other host component, such as a package substrate structure, interposer structure, or the like. As used herein, an IC die structure may include any monolithic integrated circuit device that provides electrical, compute, memory, or similar functionality. An IC die structure may itself comprise more than one monolithic integrated circuit device. For example, an IC die structure may comprise two vertically stacked IC dies or two coplanar IC dies. IC dies within an IC die structure may be directly bonded to each other or coupled through some intermediate routing structure. IC die structures in accordance with embodiments herein may be referred to as “chiplets,” “chiplet dies,” “dice,” “tiles,” or “chips,” for example. While the terms chiplet and IC die or chip may be used interchangeably, a fully functional ASIC is typically considered an IC die or chip while a chiplet or tile would have more limited functionality, for example supplementing one or more other IC chiplets that are to be part of the same multi-chiplet device. A chiplet or tile may, for example, be a wireless radio circuit, microprocessor core, electronic memory circuit, floating point gate array (FPGA), power management and/or power supply circuit, or include a MEMS device.

In the context of hybrid bonding IC die structures, self-alignment assisted assembly (SA3) may facilitate greater die-to-wafer hybrid bonding (D2 W HB) throughput by reducing the fine alignment burden. In some exemplary SA3 processes, bonding regions are incorporated into “biphilic” or “heterogeneous” surface structures on either (or both) an IC die structure or (and) a base substrate structure. As used herein, biphilic/heterogeneous surfaces have a high wettability contrast between their distinct regions. As described further herein, a high wettability contrast can be achieved by physical patterning (e.g., creating trenches around the bonding area to confine liquid via the canthotaxis effect), chemical patterning (e.g., depositing hydrophobic coatings to lower surface energy around the bonding area), or combinations of the two (e.g., creating trenches with hydrophobically coated sidewalls surrounding the bonding area).

Within a biphilic surface structure one region has high wettability relative to another region of low wettability. This wettability contrast can improve control of liquid droplet spreading such that a liquid droplet may be confined on a bonding site of either (or both) an IC die structure or (and) a base substrate structure. Surface tension of the droplet acts to passively fine-align the IC die structure as the droplet evaporates, leaving the bonding regions in contact and ready for hybrid bonding. At room temperature, attractive surface forces between the dielectric regions on the IC die structure and a base substrate structure may suffice to temporarily affix the two. A hybrid bond may be subsequently formed through application of pressure and/or elevated temperature to form and/or strengthen bonds between the metal features (e.g., copper pads) dispersed within surrounding dielectric material. Once bonded, the metal features form a composite metal feature that electrically interconnects an IC die structure and a base substrate structure. In some embodiments, however, bonding may be dielectric-dielectric only or metal-metal only (e.g., for thermal applications or some RF applications).

Accordingly, with SA3, a bonder may pick and place an IC die structure upon a base substrate structure in reliance on coarse alignment (e.g., ˜ 25-50 μm) alone, enabling fast assembly. When a liquid droplet is confined to a bonding region between the IC die structure and the base substrate structure, capillary forces and liquid surface tension induce alignment with high positional accuracy (e.g., <200 nm) due to biphilic or transition structures on mating surfaces of the IC die structure and/or base substrate structure. Such biphilic or heterogenous structures may therefore be more specifically referred to as “self-alignment features” or “SA3 features.”

The inventors have noted that while the relationship between droplet energy and IC die alignment is favorable for IC die structures that have low warpage, the lowest energy state of a droplet surface may not correspond to an ideal alignment condition for IC die structures having greater warpage. Also, warpage within an IC die structure may cause part of the die to contact a surface of the base substrate structure at a point in time when there is still relatively large liquid droplet volume, which may interfere with passive alignment. Generally, warpage increases with thinner IC die structures. For example, out-of-plane displacement of a surface of an IC die structure comprising a typical silicon die substrate layer may increase by more than two orders of magnitude as thickness of the silicon substrate is reduced from 50 μm to 0.5 μm. SA3 attachment of hybrid bondable IC die structures may therefore become increasingly challenging as IC die structure structures are vertically scaled.

As described further below, embodiments herein comprise hybrid bonding of an IC die structure to a substrate structure as facilitated by liquid droplet-based fine alignment. In some embodiments, to enable superior alignment performance, the IC die structure is provided (or received) in an initial state having sufficiently low warpage and high planarity of the bonding surface. Generally, in this initial state the IC die structure is of sufficient thickness for warpage to be low. Following fine alignment and attachment of the IC die structure to the substrate structure, the IC die structure is further processed to reduce its thickness significantly below its initial thickness. This thickness reduction may be performed to any extent desired for z-scaling the hybrid bonded composite structure. As described further below, in some embodiments the IC die structure is polished back, for example thinning the IC die substrate material layer. In some alternative embodiments, a sacrificial die-level carrier is incorporated into the IC die structure, and the die-level carrier is removed (e.g., through etching, grinding or debonding) after die bond. Accordingly, embodiments herein z-scale an IC die structure at a point in assembly downstream of a liquid droplet-based fine alignment operation so that the fine alignment may be practiced with advantageously planar bonding surfaces.

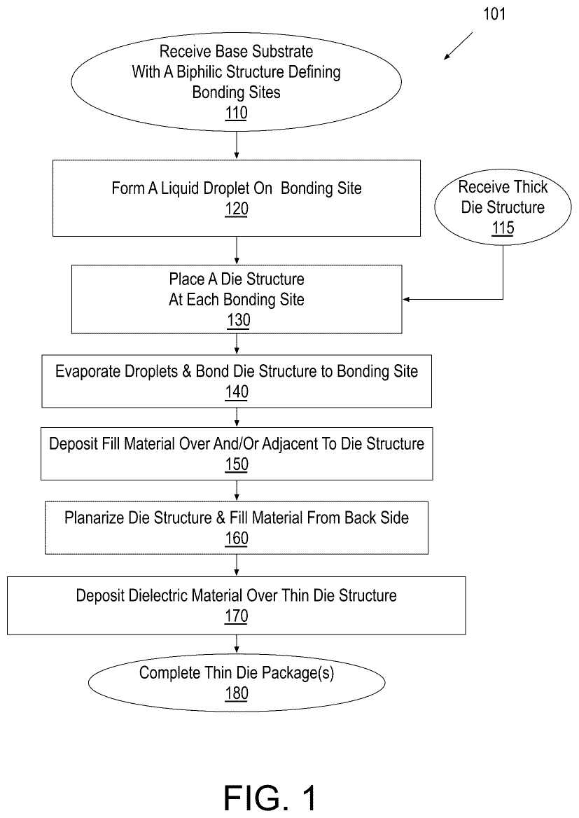

FIG. 1 is a flow diagram illustrating self-alignment assisted assembly methods 101 for thin integrated circuit (IC) die structures, in accordance with some first embodiments. In methods 101, IC die structures of sufficiently low warpage and mechanical strength are assembled to a base substrate structure according to one or more SA3 techniques. After they are hybrid bonded, the IC die structures are thinned, for example with a backside polishing process that may be performed at a wafer or panel level. Methods 101 may be practiced, for example, to form one or more of the assemblies described elsewhere herein. Methods 101 are illustrated as including several discrete blocks to ensure clarity of description. However, in practice the number of blocks, and/or order of blocks, may be modified without departing from the principles illustrated by methods 101.

Methods 101 begin at input 110 where a base substrate structure is received. The base substrate structure may be a portion of any wafer, panel, or strip, etc. that is suitable for direct bonding with one or more IC die structures. A bonding region where an IC die structure is to be attached is integrated into one or more biphilic surface structures that are suitable for SA3 assembly.

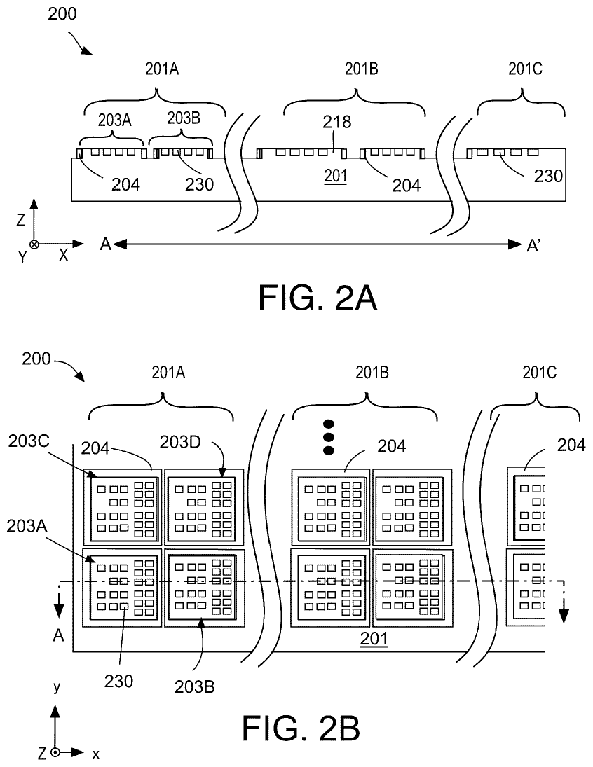

FIG. 2A is a cross-sectional view of a wafer (or panel) 200 comprising a plurality of aggregated “base” or “host” substrate structures 201A, 201B, 201C. In the illustrated example, each base substrate structure 201A-201C comprises one or more biphilic surface structures on a first (e.g., top) side of one or more substrate materials 201.

Substrate materials 201 may vary widely according to implementation. In some embodiments where each base substrate structure 201A-201C is a package substrate structure or package interposer structure, substrate materials 201 may include one or more structural material layers, such as silicon (e.g., monocrystalline), sapphire, or glass. Substrate materials 201 may include any of those found in an integrated circuit wafer having, such as semiconductor materials (e.g., silicon, germanium, GaN, GaAs, InP, InGaAS, etc), on-die interconnect layers (e.g., copper, aluminum, tantalum, other metals), and on-die dielectrics (e.g., silicon dioxide, carbon-doped silicon dioxide, silicon nitride, silicon carbide, etc.). For glass embodiments, the structural material may be predominantly silica (e.g., silicon and oxygen) and may further include one or more elements such as hydrogen, carbon and/or metals, such as, but not limited to copper, silver, gold, aluminum, beryllium, magnesium, calcium, strontium barium, or radium. Additional dopants (e.g., boron, phosphorus) may also be present in the structural material (e.g., borosilicate glass, etc.).

A package substrate structure or interposer structure may include one or more metallized redistribution or electrical routing levels (not depicted) embedded within a package dielectric material. The package dielectric material may have been built up on one or more side of a structural material layer, for example. Structural material layers may be retained or ultimately discarded so that substrate materials 201 may comprise only package dielectric material and embedded routing metallization. Package dielectric material may be any organic dielectric, such as, an epoxy resin, phenolic-glass, or a resinous film such as the GX-series films commercially available from Ajinomoto Fine-Techno Co., Inc. (ABF). Package dielectric material may comprise epoxy resins (e.g., an acrylate of novolac such as epoxy phenol novolacs (EPN) or epoxy cresol novolacs (ECN)). In other examples, package dielectric material includes aliphatic epoxy resin, which may be monofunctional (e.g., dodecanol glycidyl ether), difunctional (butanediol diglycidyl ether), or have higher functionality (e.g., trimethylolpropane triglycidyl ether).

Substrate materials 201 may include one or more IC die structure (not depicted). In some embodiments, an IC die structure is embedded within package dielectric material. In other embodiments, each base component 201A-201C is an IC die structure. Such IC die structures may be fully functional ASICs, or may be chiplets or tiles of more limited functionality to supplement one or more other IC die structures that are to be part of the same multi-chip device. For embodiments where base substrate structure 201A-201C is an IC die structure, substrate materials 201 may include any of those materials typical of monolithically fabricated IC dies, such as, but not limited to, a device material layer and/or a silicon (e.g., monocrystalline) layer, and inorganic dielectric materials (e.g., comprising at least 20 atomic % of one or more of silicon, oxygen, or nitrogen).

Base substrate structures 201A-201C have biphilic or transition structures with a wettability contrast between bonding region 203A and 203B of high wettability where a liquid droplet is to be formed, and a laterally adjacent peripheral region 204 of low wettability that is to confine the liquid droplet. Although the liquid may vary (polar or non-polar, etc.), in exemplary SA3 embodiments employing water, the bonding region of high wettability is hydrophilic (i.e., inducing a water droplet to have a contact angle of less than) 90°. A water droplet will therefore tend to spread out over regions 203A-B as the liquid minimizes its surface energy. The adjacent region 204 of low wettability is hydrophobic (i.e., inducing a water droplet to have a large contact angle of greater than) 90°. A water droplet on regions 203A-B will tend to minimize contact with region 204.

For exemplary embodiments where bonding regions 203A and 203B are a hydrophilic material, regions 203A-B advantageously comprise one or more metal features 230 embedded in and/or dispersed over a dielectric material 218. Each of metal features 230 may comprise any metal known to be suitable for direct bonding. Metal features 230 may be predominantly Cu, for example. One or more of metal features 230 may be electrically coupled to base substrate routing metallization and/or circuitry (not depicted). Metal features 230 may therefore both electrically couple and physically affix substrate structures 201A-201C to an IC die structure.

Dielectric material 218 may have any chemical composition suitable for hybrid bonding. Dielectric material 218 is advantageously an inorganic material, for example comprising at least 20 atomic % of one or more of silicon, oxygen, or nitrogen. In some embodiments, dielectric material 218 is primarily silicon and oxygen (e.g., SiO₂), primarily silicon and nitrogen (e.g., Si₃N₂), or primarily silicon, oxygen and nitrogen (e.g., SiₓO_{y}Nₓ), any of which may further comprise one or more dopants, such as carbon. Inorganic dielectric materials are nevertheless distinct from organic dielectrics (e.g., epoxy resins and phenolic-glasses), which have much higher carbon content and a higher percentage of carbon-hydrogen bonds.

Region 204 may include any chemical coating or thin film material and/or topographic structure that creates a hydrophobic boundary adjacent to one or more edges of bonding regions 203A-B. In some embodiments, the hydrophobic material is a self-assembled monolayer (SAM) material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). Other SAM embodiments may comprise disulfides, amines, azoles, amides, imides, pyridine derivatives, cyanoacrylate derivatives or other moieties which include a sulfur atom or a nitrogen atom. SAM reactions typically form monolayer molecules aligned with each other in a uniform manner. Such a molecule may be introduced in the vapor phase and “self-assemble” by forming a highly selective bond at the surface and orientating itself perpendicular to the face of the surface. However, non-SAM based materials or films are also possible. In some embodiments, region 204 is, or includes, a polymer thin film such as a siloxane (e.g., PDMS and derivatives, HMDSO), a silazane (HMDS), a polyolefin (e.g., PP), or a fluorinated polymer (e.g., PTFE, PFPE, PFDA, C₄F₈ plasma polymerized films, etc.). In some advantageous embodiments, region 204 comprises a material of a chemical composition having at least ten atomic percent (at. %) carbon or at least ten at. % fluorine.

Region 204 may additionally, or in the alternative, comprise topographic features that increase wettability contrast relative to bonding regions 203A-B. A topographic trench within region 204 may, for example, improve wettability contrast between region 204 and bonding regions 203A-B. Such a topographic feature can change a liquid droplet's effective contact angle to greater than 90° and thereby alter the surface energy characteristics of the droplet. In some further embodiments, region 204 has significantly higher average surface roughness than bonding regions 203A-B. Region 204 may be roughened with any surface texturing techniques, such as laser surface roughening. Roughened surfaces may have any surface roughness greater than the surface roughness of a bonding region. For example, bonding regions 203A-B may have a low surface roughness (e.g., <30 nm average roughness) while region 204 has high surface roughness (e.g., >50 nm average roughness). In some embodiments, the average surface roughness of region 204 is at least twice the average surface roughness of the surface of a bonding region and may be five, ten, or twenty times that of a bonding region. As used herein, average roughness (or center line average) is as described in ASME B46.1. Average roughness is the arithmetic average of the absolute values of profile height deviations from a mean line that is recorded for an evaluation length. Average roughness may be measured, for example, with a profilometer comprising a stylus that is traversed over a surface. For region 204 having a longitudinal length in a first dimension (e.g., coincident with x-axis), average roughness may be measured over a distance roughly 60-70% of the longitudinal length while remaining at about a centerline of a transverse width of region 204 that is in a dimension substantially orthogonal to the first dimension (e.g., coincident with y-axis).

FIG. 2B is a plan view of base wafer or panel 200, in accordance with some embodiments. The A-A′ cross-sectional plane illustrated in FIG. 2A is denoted in FIG. 2B by a dashed line. In this example, each base substrate structure 201A-201C has a plurality of bonding regions 203A-203D and each of bonding regions 203A-D is to bond with one IC die structure. As shown in FIG. 2A and FIG. 2B, region(s) 204 are adjacent to bonding regions 203A-D. Bonding regions and adjacent regions may be of contrasting feature shapes, and/or of contrasting surface roughness, and/or of contrasting chemical composition. In the example illustrated in FIG. 2A-2B, regions 204 are in contact with a sidewall of bonding regions 203A-D. Bonding regions 203A-D match a desired layout of IC die structures that are to be attached to each base substrate structure 201A-201C. Regions 204 are within a trench formed within one or more substrate materials 201 and/or regions 203A-D are on a pedestal or mesa over substrate materials 201.

Region 204 is adjacent to multiple non-parallel edges of each bonding region (e.g., 203A, 203B), and as illustrated in FIG. 2B, surrounds a perimeter of a bonding region (e.g., 203A, 203B). Region 204 may be formed on sidewalls bonding regions according to any suitable technique(s). For example, a conformal hydrophobic material layer may be formed on exposed surfaces of bonding regions, for example with either a spin coating or a conformal vapor deposition process. The conformal hydrophobic material layer may then be patterned with an anisotropic “spacer” etch.

Returning to FIG. 1, methods 101 continue at block 120 where a liquid droplet is formed on each bonding region of the base substrate structure. Any techniques suitable for the liquid, such as vapor condensation or direct liquid dispense (i.e., printing) may be practiced at block 120 as embodiments are not limited in this respect. In some exemplary embodiments, a water droplet is dispensed at block 120. However, alternative polar (e.g., alcohols) or non-polar (e.g., solvents) liquids may be dispensed at block 120 depending on the nature of the base substrate structure's wettability contrast.

A thick die structure is received as a second input to methods 101. A liquid droplet may be formed on the IC die structure either in addition to the droplet formed on the bonding region at block 120, or as an alternative to the droplet formed at block 120. Methods 101 continue at block 130 where the IC die structure received at input 115 is placed over a bonding region of the base substrate structure.

The thick die structure received at input 115 may comprise a single IC die or may comprise any number of IC dies assembled (e.g., hybrid bonded) into a coplanar or 3D IC die structure. The IC die structure may, but need not, further comprise organic dielectric materials and/or metallization levels built up upon an IC die surface with a suitable semi-additive process (SAP). Regardless of the materials present, the IC die structure is of sufficient thickness to ensure advantageous bonding surface planarity for reliable droplet-based alignment to the base substrate structure.

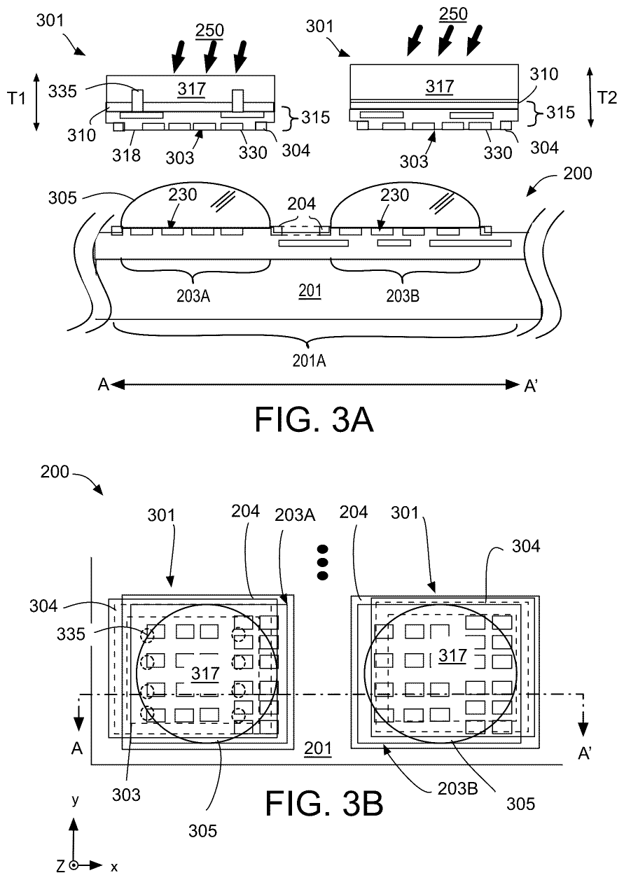

FIG. 3A is a cross-sectional view of thick IC die structures 301, 302 undergoing an initial coarse alignment 250 to base wafer or panel 200. As so aligned, IC die structures 301, 302 are placed upon liquid droplets 305 confined to bonding regions 203A, 203B, in accordance with some embodiments. Coarse alignment 250 may be performed, for example, with pick-and-place equipment. Such equipment may be capable of positional accuracy within 25-50 μm in each of the x-dimension and y-dimension, for example. FIG. 3B is a plan view of coarse alignment 250 and placement of IC die structures 301, 302, in accordance with some embodiments. Some alignment error is illustrated in FIG. 3B with liquid (e.g., water) droplet 305 to correct the misalignment during a passive fine alignment (e.g., via capillary forces, etc.) phase until the droplet evaporates. In exemplary embodiments, the fine alignment is advantageously to within 200 nm in each of the x-dimension and orthogonal y-dimension.

In the exemplary embodiments illustrated by FIG. 3A and FIG. 3B, IC die structures 301 and 302 each comprise an IC die substrate material 317, a device layer 310 in contact with IC die substrate 317, and IC die metallization levels 315 over device layer 310. IC die structure 301 further illustrates an example including through substrate vias (TSVs) 335 extending from device layer 310 and into IC die substrate material 317. Although the chemical composition of IC die substrate material 317 may vary with implementation, in exemplary embodiments IC die substrate material 317 is a silicon (e.g., monocrystalline) layer. IC die substrate material 317 may also be of alternative compositions, such as, but not limited to, germanium (Ge), silicon germanium alloys (SiGe), gallium arsenide alloys (GaAs), indium phosphide alloys (InP), gallium nitride alloys (GaN), silicon carbide alloys (SiC), etc. Device layer 310 comprises active devices (not depicted). In some embodiments, the active devices within device layer 310 are field effect transistors (FETs). The FETs may be of any architecture (e.g., planar, non-planar, single-gate, multi-gate, stacked nanosheet, etc.) and may have a feature pitch of 10-30 nm, for example. Additionally, or in the alternative, device layer 310 may include active devices other than FETs. For example, device layer 310 may include electronic memory structures, spin valves, or the like.

IC die structures 301, 302 comprise IC die metallization levels 315 on a front side of device layer 310. In exemplary embodiments, metallization levels 315 include die metallization features 330 embedded within a dielectric material 318. While IC die metallization features 330 may have any composition(s) of sufficient electrical conductivity, in exemplary embodiments, IC die metallization features 330 are predominantly Cu. In other examples, metallization features 330 are predominantly other than Cu, such as, but not limited to predominantly Ru, or predominantly W.

In exemplary embodiments, IC die structures 301, 302 further comprise a biphilic surface structure corresponding to a complementary surface structure on base substrate structures 203A, 203B, respectively. For IC die structures 301 and 302, a bonding region 303 comprises an uppermost one of metallization features 330. Bonding region 303 may have any feature pitch compatible with bonding region 203A. In some exemplary embodiments, individual ones of metallization features 330 correspond to individual ones of metallization features 230, both having a feature pitch in the range of 100 nm to 1 μm, for example. Metallization features 330 may have any suitable composition and may be of substantially the same composition as metallization features 230, for example. Bonding region 303 further comprises dielectric material 318, which may have any of the inorganic compositions described for dielectric material 218. Bonding region 303 is therefore compatible for bonding with a bonding region of base substrate structure 201A.

Each IC die structure further comprises a region 304 adjacent to a bonding region 303. Region 304 may include any of the properties or characteristics discussed elsewhere herein for region 204. In some embodiments, bonding region 303 and adjacent region 304 are fabricated according to any of the techniques discussed above for corresponding regions of base substrate structure 201A. The biphilic surface structures on base substrate structure 201A and the biphilic surface structures on IC die structures 301, 302 may be substantially the same (as illustrated) or they may differ compositionally and/or structurally.

As further illustrated by dashed line in FIG. 3B, region 304 substantially surrounds a perimeter of bonding region 303. Region 304 may be a single continuous material and/or structure with a hydrophobic surface. Alternatively, region 304 may comprise multiple discontinuous hydrophobic material and/or structural segments delineating a perimeter about two or more edges of bonding region 303. Although FIG. 3A and FIG. 3B illustrate an example where two IC die structures 301, 302 are placed adjacent to one another upon one base substrate structure 201A, one or more IC die structures may be placed upon a particular base substrate structure.

As shown in FIG. 3A, IC die structure 301 has an initial thickness T1 sufficient to ensure adequate planarity of bonding region 303. IC die structure 302 likewise has an initial thickness T2 sufficient to ensure adequate planarity of bonding region 303. Depending on implementation, thickness T1 may be substantially equal to thickness T2, for example where IC die structures 301 and 302 are from a same IC die technology or even from the same source wafer. Thicknesses T1 and T2 may also differ significantly, for example where IC die structures 301 and 302 are from a different IC die technology or at least from the different source wafers. In exemplary embodiments, thicknesses T1 and T2 are both greater than 50 μm, and may be 100 μm, or more. In some embodiments, the thickness of IC die substrate material 317 is at least 50 μm (e.g., 50, 75, 100 μm, or more) for each of IC die structures 301, 302. With such a thickness, warpage of IC die structures 301, 302 can be minimal (e.g., with an out of plane displacement of less than 2 μm) over an area or footprint of bonding region 303.

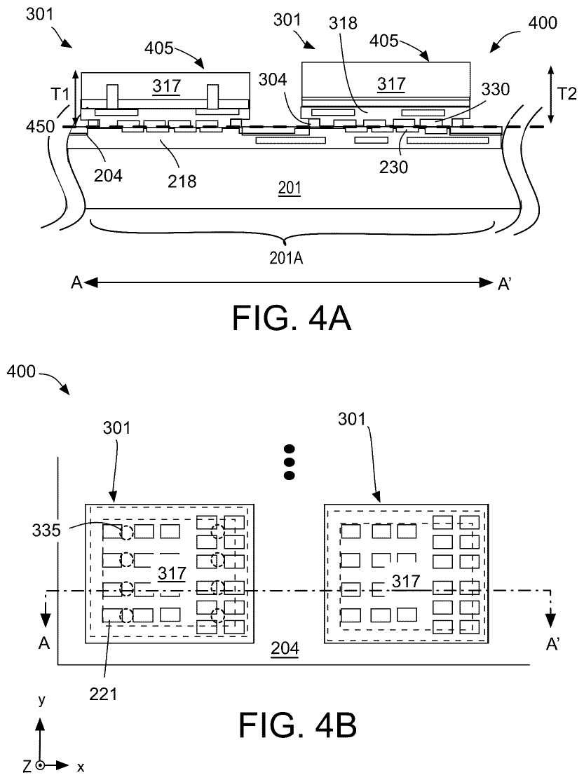

Returning to FIG. 1, methods 101 continue at block 140, where a liquid droplet between an IC die structure and base substrate structure is evaporated, bringing the IC die structure bonding region in direct contact with the base substrate bonding region. The IC die structure may then be bonded to the base substrate structure according to any suitable hybrid bonding technique(s). FIG. 4A illustrates an exemplary hybrid bonded composite structure 400 where IC die structures 301 and 302 are now in contact with base substrate structure 201A along bonding interface 450, denoted by a thick dashed line. As shown, metal features 230 are in direct contact with at least a portion of corresponding ones of metal features 330. Dielectric material 218 of base substrate structure 201A is likewise in direct contact with dielectric material 318 of IC die structures 301 and 302. An extent of lateral offset between metal features 230 and 330 along bonding interface 450 is indicative of fine alignment tolerances.

Individual ones of regions 204 on base substrate structure 201A are co-located with corresponding ones of regions 304 on IC die structures 301 and 302. Regions 204 may also be in direct contact with regions 304 along bonding interface 450, although they may not interdiffuse or meld to form a unified composite structure even after a thermos and/or compression bonding process. Regions 204 may also be physically spaced apart from regions 304 across bonding interface 450. As both IC die structures 301 and 302 are bonded along a substantially planar bonding interface 450, IC die backside surface 405 may not be co-planar if there is a difference between die structure thicknesses T1 and T2.

Returning to FIG. 1, methods 101 continue at block 150 where a fill material is deposited over the bonded IC die structure, and over portions of the base substate structure that is not occluded by an IC die structure. The fill material deposited at block 150 is advantageously a dielectric material. The fill material may be an inorganic dielectric material or an organic dielectric material, for example any of those previously described. In exemplary embodiments the fill material is deposited to a thickness at least equal to the thickness of the IC die structure. The fill material may be deposited by any technique known to be suitable for the chosen composition and thickness of material. In some embodiments, a dielectric fill material may be applied with a spin-on or spray-on process and subsequently cured. In other embodiments, a dielectric fill material may be deposited with a chemical vapor deposition (CVD) process. In still other embodiments, a dielectric fill material may be deposited at block 150 with a molding process. Depending on the deposition process, the dielectric fill material may be planar along a length spanning the IC die structure and extending beyond an edge of the IC die structure.

At block 160, the fill material is planarized, for example with a chemical mechanical planarization (CMP) system or any other suitable grinder and/or polisher. The planarization process performed at block 160 also thins the bonded IC die structure by a significant amount. Planarization processes may thin the bonded IC die structure to the limit of workpiece total thickness variation (TTV). In some embodiments, the thickness of an IC die substrate (e.g., silicon layer) is reduced by at least 30%, and advantageously at least 80%.

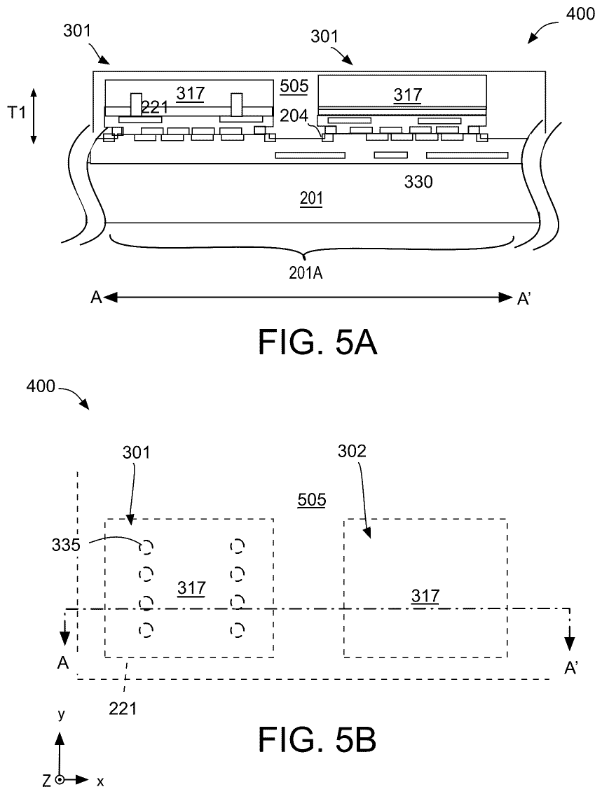

In the example illustrated in FIGS. 5A and 5B, composite structure 400 further includes a dielectric material 505 over IC die structures 301 and 302. Dielectric material also substantially backfills a gap between adjacent edge sidewalls of IC die structures 301 and 302. In some embodiments, dielectric material 505 is one or more of any of the inorganic dielectric compositions previously described. In some other embodiments, dielectric material 505 is one or more of any of the organic dielectric compositions previously described. As illustrated, dielectric material 505 is substantially planarized across IC die structures 301 and 302. Such planarization may be attributable to a dielectric deposition process and/or a post-deposition polishing or CMP process.

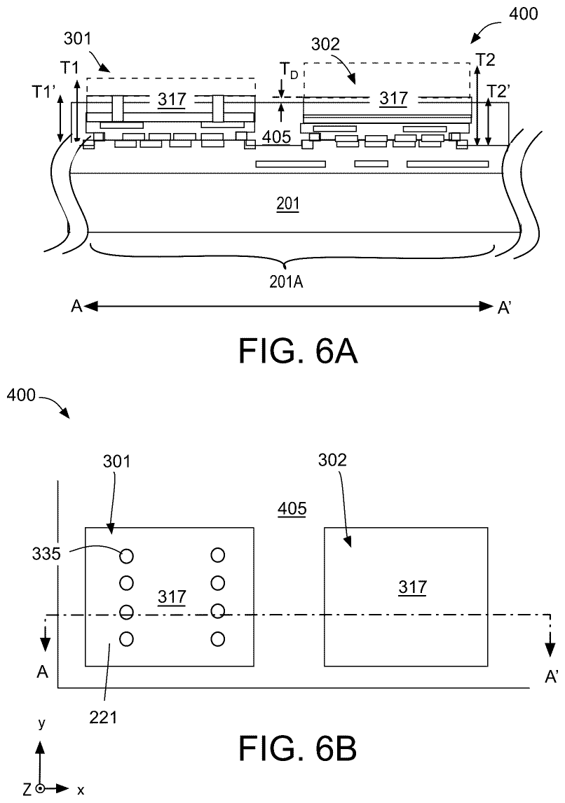

FIGS. 6A and 6B illustrate a backside thinning of IC die structures 301 and 302. As shown, IC die structure 301 is reduced from thickness T1 to a lesser thickness T1′. Concurrently, IC die structure 302 is reduced from thickness T2 to a lesser thickness T2.′ For the exemplary embodiment, thickness T2′ is approximately equal (e.g., to within 10%) to thickness T1′ regardless of any difference between the initial thicknesses T1 and T2. Although a substantially planar process, a backside polish may be expected to display some dishing characteristics stemming from different rates of erosion for each of IC die substrate material 317 and dielectric material 505. A recess in one of IC die substrate 317 or dielectric material 505, relative to the other, may be characterized as dishing thickness T_{D}. Dishing thickness T_{D} is typically small, for example less than 10% of IC die structure thickness T1′ and/or T2′. The illustrated co-planarity of the backside of IC die substrates 317, as well as the presence of some non-zero dishing thickness T_{D}, is indicative of a post-bond polishing process in accordance with some embodiments herein. The dishing is shown as a flat section but it can have certain curvature. Similarly, the die edges may also be slightly rounded or the dies may have concave shape.

As shown in FIGS. 6A and 6B, backside thinning of IC die structures 302 exposes TSVs 335, rendering IC die structure 301 ready for backside electrical interconnection. The difference between IC die structure thicknesses T1 and T1′ may therefore be any amount sufficient to expose TSVs 335, which may vary as a function of the initial thickness of IC die substrate material 317. In some embodiments where IC die thickness T1 is over 50 μm, thickness T1′ is less than 50 μm. Hence, for some embodiments where IC die substrate material 317 has an initial thickness T1 over 50 μm during droplet-based fine alignment, IC die substrate material 317 may be thinned by 30-50%, or more so that thickness T1′ is less than 50 μm. In some specific embodiments, IC die substrate material may be thinned to less than 10 μm (e.g., 0.5-5 μm). In other embodiments, an IC die may have metallization on both sides of the device layer and grinding to remove the non-active substrate also reveal the backside metallization for electrical connections.

Returning to FIG. 1, methods 101 continue at block 170 where a backside of the bonded IC die structure is encapsulated by depositing one or more dielectric material layers over the thinned die structure. Such dielectric material may be deposited conformally, forming a layer of substantially equal thickness over underlying structures regardless of surface planarity. Dielectric material may also be deposited with a non-conformal flowable and/or planarizing process. Methods 101 are then completed at output 180 where any known processing may be performed to arrive at a singulated thin hybrid-bonded IC die package/assembly.

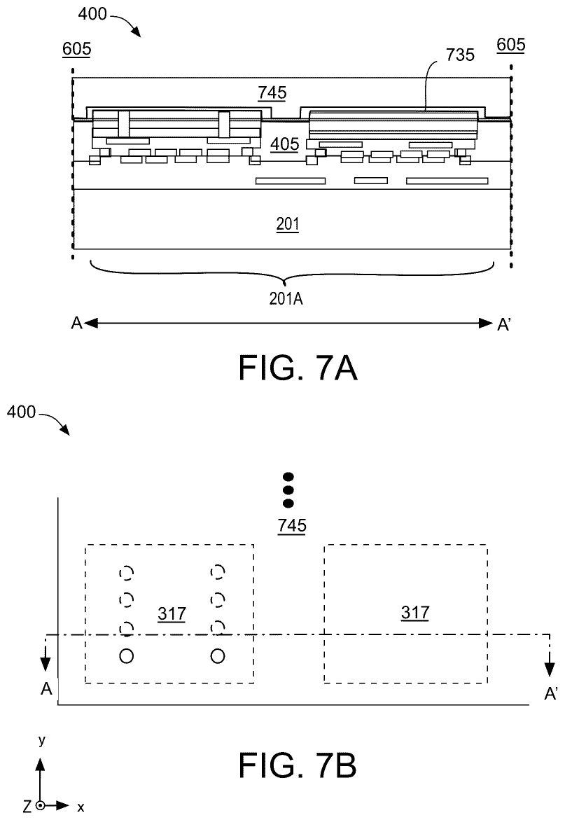

FIGS. 7A and 7B illustrate an exemplary composite structure 400 following deposition of a conformal dielectric material layer 735 in direct contact with IC die substrate 317. As shown, dielectric material layer 735 follows any dishing pattern over the area of composite structure 400. Dielectric material layer 735 may be, for example, any of the inorganic dielectric materials described elsewhere herein. A planarized dielectric material layer 745 is over, and in direct contact with, dielectric layer 735. Dielectric material layer 745 may also be any of the inorganic dielectric materials described elsewhere herein. In some exemplary embodiments, dielectric material layer 745 has a different composition than dielectric material layer 735. One or more levels of routing, RDL and/or interconnect metallization (not depicted) may be embedded within dielectric material layers 735 and 745. One or more additional IC die structures (not depicted) may be further stacked upon the composite structure, for example using substantially the same SA3-facilitated hybrid bonding techniques described above. In certain embodiments, dielectric material 405 may be sacrificial and is completely removed. In such scenarios, the resulting structures will have only the final dielectric 745 but may still show die edge shape variations.

Following singulation 605 (denoted by dashed lines), composite structure 400 may be incorporated into any system. For example, composite structure 400 may be further packaged in any manner suitable for a single IC die. Composite structure 400 may be integrated into any electronic device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

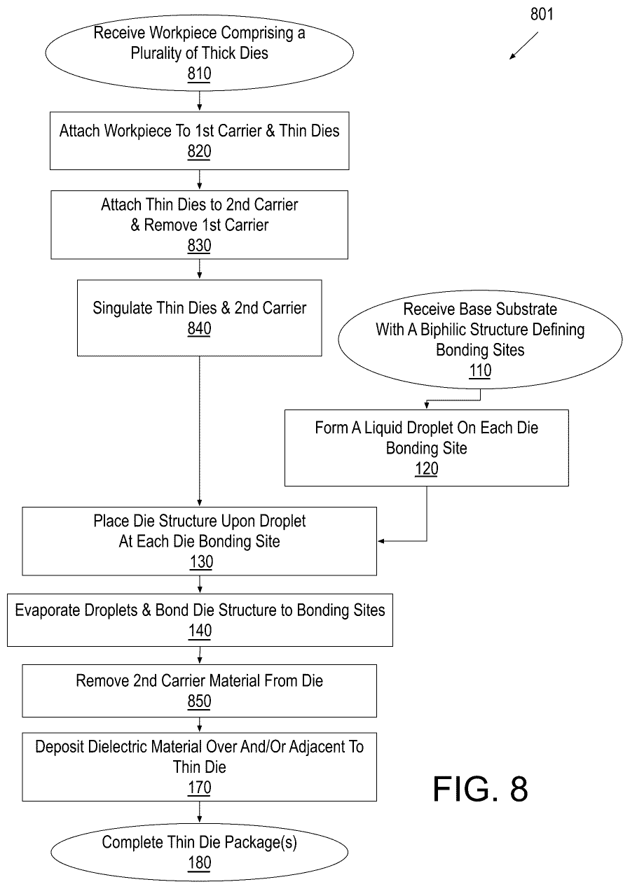

FIG. 8 is a flow diagram illustrating methods 801 for self-alignment assisted assembly of thin IC die structures, in accordance with some alternative embodiments. In contrast to methods 101, methods 801 generally entail the incorporation of a sacrificial die-level carrier within an IC die structure that is fine aligned by one or more SA3 techniques and hybrid bonded. The die-level carrier, taking the place of thick IC die substrate material, may be removed after die bonding. Methods 801 may be practiced to form one or more of the assemblies described elsewhere herein. Methods 801 are illustrated to include illustrative discrete blocks to ensure clarity of description. In practice, the number of blocks, and/or order of blocks, may be modified without departing from the principles illustrated by methods 801.

Methods 801 begin at input 810 where a workpiece comprising a plurality of thick IC dies is received. The workpiece may be a monolithic wafer, for example, and the IC dies may be any ASIC, chiplet or tile, etc. as embodiments are not limited in this respect. The workpiece may be of any thickness sufficient to maintain surface planarity and/or minimal warpage. A back side of the IC dies is then thinned at block 820 after the workpiece is attached to a front-side carrier suitable for maintaining surface planarity and/or minimal warpage after thinning.

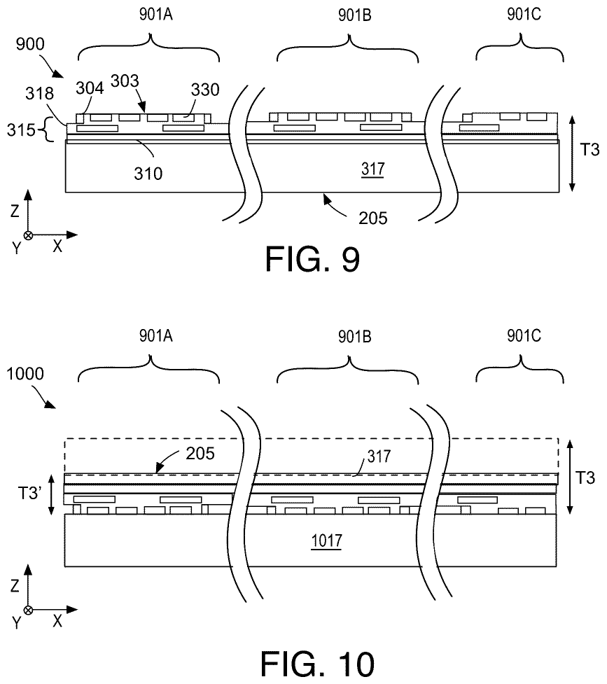

FIG. 9 is a cross-sectional view of a monolithic IC wafer 900 comprising a plurality IC die structures 901A, 901B, 901C. IC dies 901A-C may be any ASIC, chiplet or tile and advantageously comprise biphilic surface structures on their front side, opposite IC die substrate material 317. As previously described elsewhere herein, biphilic surface structures further comprise a bonding region 303 and an adjacent peripheral region 304 having wettability contrast with bonding region 303. The biphilic surface structures may have any of the topographic and/or surface chemistry attributes previously described, for example. IC dies 901A-901C include a device layer 310 in contact with IC die substrate material 317, and IC die metallization levels 315 over device layer 310. IC die metallization levels 315 further include die metallization features 330 embedded in dielectric material 318. IC die substrate material 317, device layer 310, die metallization features 330 and dielectric material 318 may each have any of the properties previously described, for example. In wafer form, IC dies 901A-901C have an initial thickness T3, which may vary with implementation. In some embodiments, thickness T3 is over 50 μm, and may be 100-500 μm, or more.

FIG. 10 is a cross-sectional view of a wafer-level assembly 1000 comprising thin IC die structures 901A-901C affixed to a frontside carrier 1017, in accordance with some embodiments. Frontside carrier 1017 may comprise one or more materials, such as, but not limited to, monocrystalline silicon or any of the glass structural material compositions previously described. Frontside carrier 1017 may be affixed to a front side of IC die 901A-901C with any reversible adhesive or clamping mechanism known to be suitable for wafer backside processing. As illustrated by dashed line, backside processing reduces initial thickness T3 to thickness T3′. In some embodiments, die substrate material 317 may be reduced to a thickness significantly less than 50 μm so that thickness T3′ may also be less than 50 μm. In some embodiments, die substrate material 317 may be thinned to be less than 10 μm (e.g., 1-5 μm). Backside processing may advantageously comprise a planar grinding and/or polishing processes. However, backside processing may also comprise a cleaving process, or any other process(es) known to be suitable for thinning die substrate material 317.

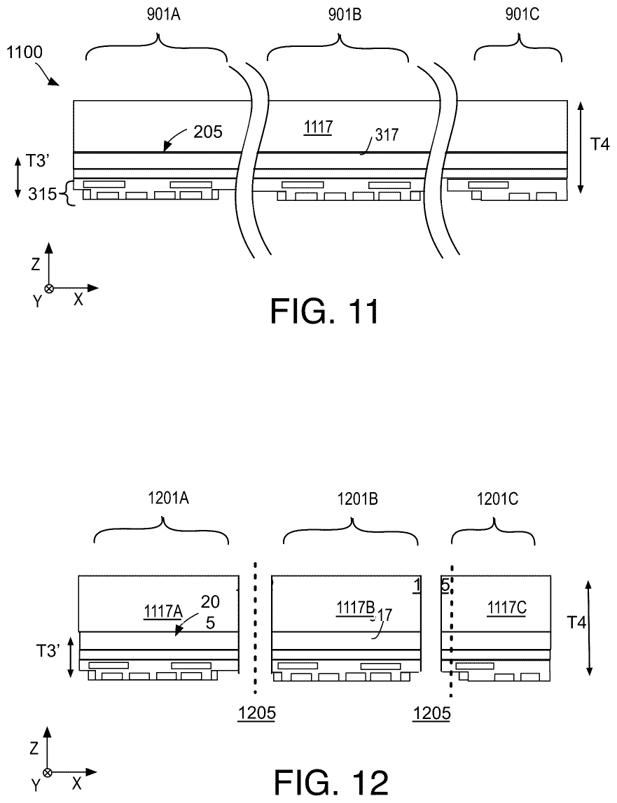

Returning to FIG. 8, methods 801 continue at block 830 where the thin IC dies are transferred from a frontside carrier to a backside carrier. Upon attaching a backside carrier, the frontside carrier may be removed to expose regions of the IC die which can be subsequently bonded to a base substrate structure. The frontside carrier may be retained and reused for another iteration of methods 801. The backside carrier is singulated along with the thin IC dies, converting the backside carrier from a wafer-level carrier into a die-level carrier. FIG. 11 is a cross-sectional view of an assembly 1100 comprising thin IC die structures 901A-901C affixed to a sacrificial carrier 1117, in accordance with some embodiments. In FIG. 11, an uppermost one of metallization levels 315 is exposed through removal of the frontside carrier.

Backside carrier 1117 may comprise one or more material layers as needed to provide sufficient structural support to maintain a threshold level of planarity. In some examples backside carrier 1117 is a glass structural material, which may have any of the glass compositions previously described. In some other examples, backside carrier 1117 is a silicon wafer or any other preform of similar flatness. In other embodiments, the backside carrier may be a deposited organic or inorganic dielectric or a plated metal backing such as copper, aluminum, silver, etc. With backside carrier 1117 attached, wafer-level assembly 1100 may have any thickness T4. Thickness T4 may vary, for example, as a function of elastic modulus of carrier 1117. Backside carrier 1117 may be affixed to IC die substrate material 317 through any suitable means. In some embodiments, an interface material layer 205 may be present between a bulk material of backside carrier 1117 and IC die substrate material 317. Interface material layer 205 may, for example, be an adhesive or a material that may be subsequently decomposed, for example through one or more of laser, chemical, or thermal processing.

FIG. 12 is a cross-sectional view of IC die structures 1201A, 1201B and 1201C following a singulation process 1205, illustrated with heavy dashed line. With the backside carrier singulated, each IC die structure 1201A-1201C comprises a corresponding die-level carrier 1117A-1117C. IC die structure 1201A-1201C retains thickness T4 and therefore maintains low warpage and/or high x-y dimensional planarity.

Returning to FIG. 8, methods 801 continue with receipt of a base substrate structure at input 110, As previously described elsewhere herein for input 110, the base substrate structure may be any substrate structure suitable for bonding with an IC die structure, and advantageously comprises biphilic surface structures defining die bonding regions. Methods 801 continue to blocks 120, 130 and 140 with a liquid droplet-based fine alignment and bonding process, each of which may be substantially as previously described in the context of methods 101 (FIG. 1).

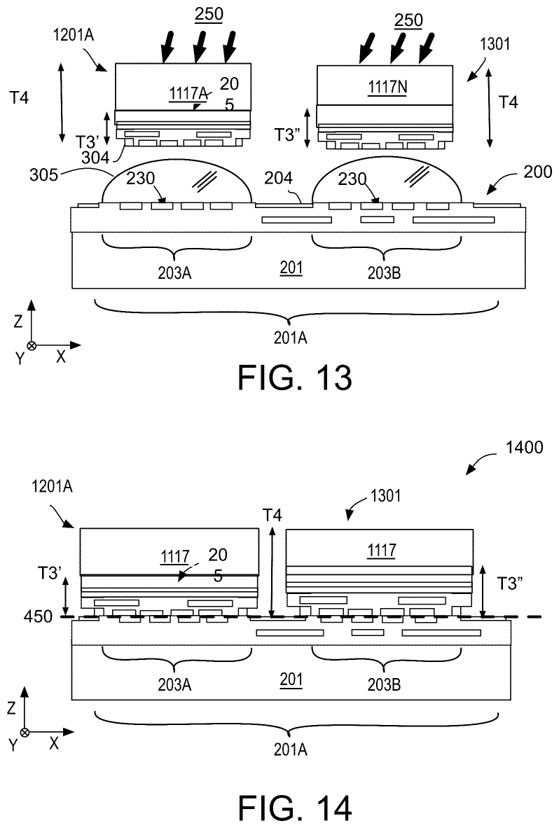

In the example illustrated in FIG. 13, IC die structure 1201A is paced upon liquid droplet 305, for example with a coarse alignment capability. Another IC die structure 1301, also comprising a die-level carrier 1117N, is placed upon another droplet on bonding region 203B defined by another biphilic surface structure on base substrate structure 201A. IC die structure 1301 may be from any source wafer and therefore may have an arbitrarily different IC die thickness T3″. IC die structure 1301 may be of substantially the same thickness T4, or not. FIG. 14 is a cross-sectional view of an assembly 1400 comprising thin IC die structures 1201A and 1301 hybrid bonded to base substrate structure 201A, in accordance with some embodiments. A hybrid bond interface 450 may be formed substantially as previously described where the IC die structure, having adequate planarity and/or sufficiently low warpage, is aligned with a passive droplet-based SA3 alignment technique.

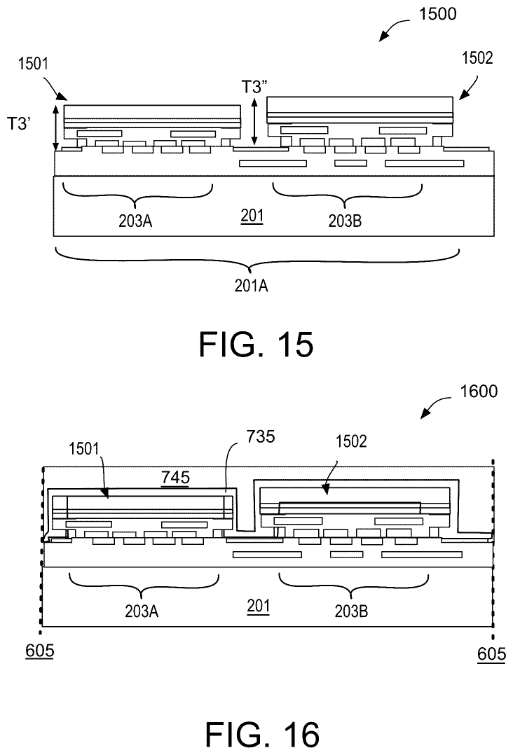

Returning to FIG. 8, methods 801 continue at block 850 where the die-level carrier is removed from the back side of a bonded IC die structure. The die level carrier may be removed by any technique, such as, mechanically delaminating the carrier or removing an adhesion layer (or other sacrificial material layer) from between the carrier and the IC die structure, for example through chemical etching, thermal decomposition, laser ablation, or exposure to UV radiation. The die level carrier may also be etched away. A backside polishing process substantially as described in the context of methods 101 may also be practiced. FIG. 15 is a cross-sectional view of an assembly 1500 comprising thin IC die structure 1501 and 1502 following removal of die-level carriers, in accordance with some embodiments. In this example, a non-planarizing process has been used to remove the carriers such that any difference between thicknesses T3′ and T3″ remains evident in assembly 1500. Such carrier removal techniques may be practiced, for example, without first depositing a fill material around the IC die structures.

Methods 801 (FIG. 8) continue at block 170 with deposition of a fill material over and/or adjacent to edge sidewalls of bonded IC die structures. Any of the materials and/or techniques previously described in the context of methods 101 (FIG. 1) may be implemented in the devices fabricated according to methods 801 (FIG. 8). Methods 801 may then end at output 180 where the thin IC die package is completed according to any techniques, for example substantially as previously described. FIG. 16 is a cross-sectional view of a composite structure 1600 comprising dielectric material layers 735 and 745 over IC die structure 1501, 1502. Each of dielectric material layers 735, 745 may have any of the compositions previously described, for example. In the illustrated embodiment, dielectric material layer 735 makes direct contact with a portion of the base substrate structure in regions not occluded by IC die structure 1501, 1502. The absence of any intervening dielectric material between dielectric material layer 735 and the base substrate structure, along with different IC die heights, is indicative of the use of die-level carriers to supplement IC die during a droplet-based fine alignment controlled through biphilic surface structures.

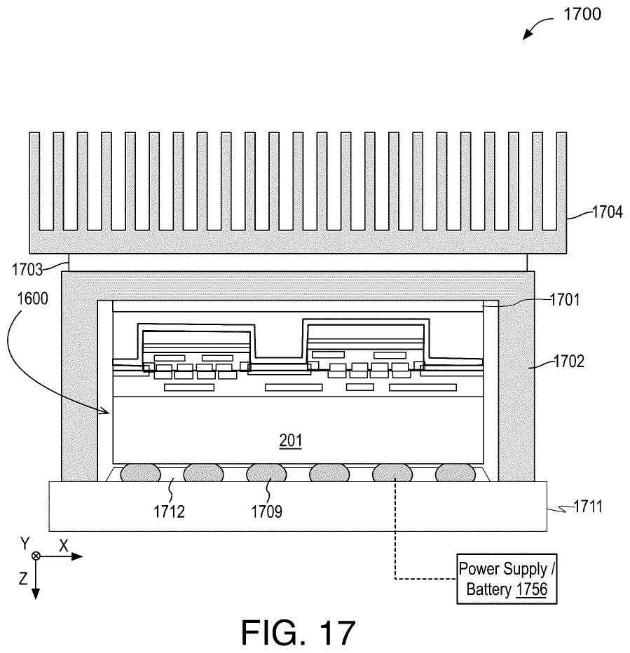

FIG. 17 is a cross-sectional view of system 1700 comprising a heat sink 1704 and a host component 1711 assembled with a hybrid bonded composite structure 1600 further comprising a thin IC die, in accordance with some embodiments. Although illustrated with an integration of composite structure 1600, system 1700 may similarly comprise composite structure 400 (FIG. 4). System 1700 may include any number of such composite structure mounted to host 1711 via interconnects 1709, which are optionally embedded in an underfill material 1712. Substrate 1711 may be a cored or coreless package substrate, interposer, or board (such as a motherboard), for example.

System 1700 further includes a power supply 1756 coupled to one or more of substrate 1711 (i.e., a board, package substrate, or interposer), composite structure 1600, and/or other components of system 1700. Power supply 1756 may include a battery, voltage converter, power supply circuitry, or the like. Microelectronic device assembly 1700 further includes a thermal interface material (TIM) 1701 over composite structure 1600. TIM 1701 may include any suitable thermal interface material. System 1700 further includes an integrated heat spreader (IHS) and/or lid 1702 in contact with TIM 1701 and extends over composite structure 1600. System 1700 further includes another TIM 1703 in contact with a top surface of IHS 1702. TIM 1703 may include any suitable thermal interface material and may be of the same composition as TIM 1001, or not. System 1700 includes a heat sink 1704 (e.g., an exemplary beat dissipation device or thermal solution) in contact with TIM 1703. System 1700 may be further integrated into a computer, such as a mobile device or server, for example.

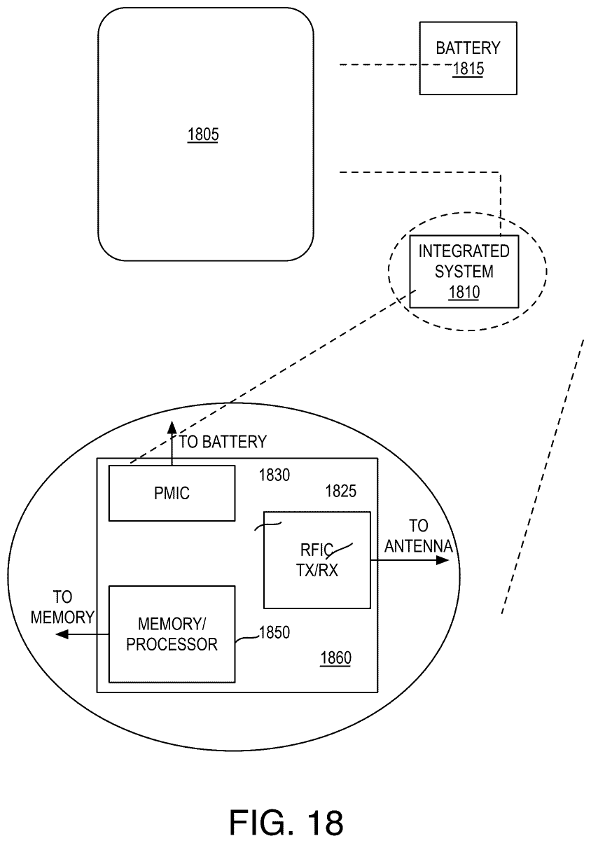

FIG. 18 illustrates an exemplary computer platform 1805 including a composite structure including a bonded IC die with biphilic surface structures proximal to a hybrid bond interface indicative of droplet-based fine alignment techniques. Platform 1805 may be a mobile computing platform and/or a data server machine, for example. A server machine may be any commercial server, for example, including any number of high-performance computing platforms disposed within a rack and networked together for electronic data processing. Platform 1805 may be any portable device configured for each of electronic data display, electronic data processing, wireless electronic data transmission, or the like. Platform 1805 may include a chip-level or package-level integrated system 1810, and a battery 1815. In some examples, the disclosed systems may be implemented in a disaggregated sub-system 1860.

Sub-system 1860 may include memory circuitry and/or processor circuitry 1850 (e.g., RAM, a microprocessor, a multi-core microprocessor, graphics processor, etc.), a power management integrated circuit (PMIC) 1830, and a radio frequency integrated circuit (RFIC) 1825 (e.g., including a wideband RF transmitter and/or receiver (TX/RX)). As shown, one or more IC dice, such as memory circuitry and/or processor circuitry 1850 may be co-packaged and/or co-assembled within a composite structure including an IC die having biphilic structures proximately to a hybrid bond interface, for example as described herein.

In some embodiments, RFIC 1825 includes a digital baseband and an analog front end module further comprising a power amplifier on a transmit path and a low noise amplifier on a receive path). Functionally, PMIC 1830 may perform battery power regulation, DC-to-DC conversion, etc., and so has an input coupled to battery 1815, and an output providing a current supply to other functional modules. As further illustrated in FIG. 18, in the exemplary embodiment, RFIC 1825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1850 may provide memory functionality, high level control, data processing and the like for sub-system 1860.

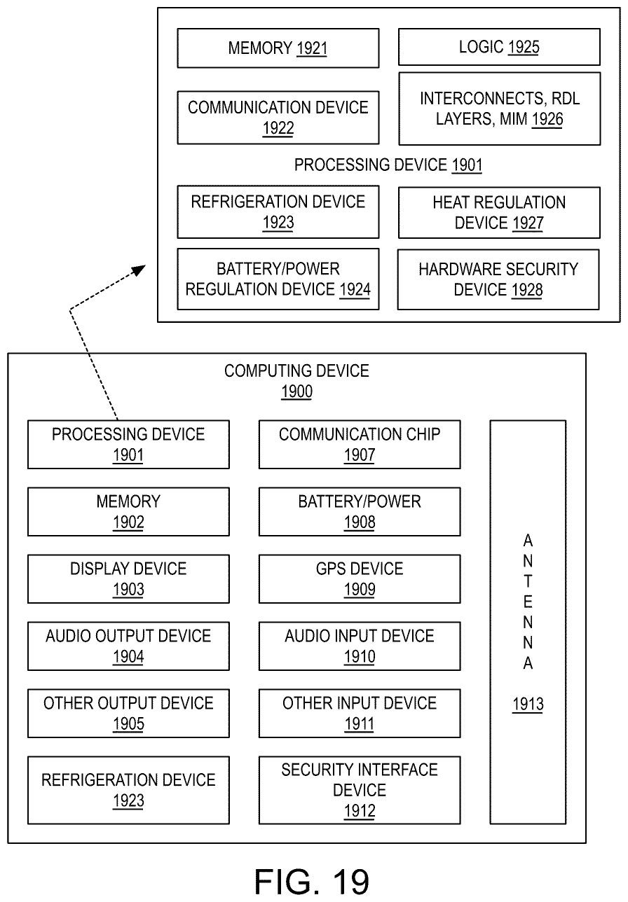

FIG. 19 is a block diagram of a cryogenically cooled computing device 1900 in accordance with some embodiments. For example, one or more components of computing device 1900 may include any of the devices or structures discussed elsewhere herein. A number of components are illustrated in FIG. 19 as included in computing device 1900, but any one or more of these components may be omitted or duplicated, as suitable for the application. In some embodiments, some of the components included in computing device 1900 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1900 may not include one or more of the components illustrated in FIG. 19, but computing device 1900 may include interface circuitry for coupling to the one or more components. For example, computing device 1900 may not include a display device 1903, but may include display device interface circuitry (e.g., a connector and driver circuitry) to which display device 1903 may be coupled.

Computing device 1900 may include a processing device 1901 (e.g., one or more processing devices). As used herein, the term processing device or processor indicates a device that processes electronic data from registers and/or memory to transform that electronic data into other electronic data that may be stored in registers and/or memory. Processing device 1901 may include a memory 1921, a communication device 1922, a refrigeration/active cooling device 1923, a battery/power regulation device 1924, logic 1925, interconnects 1926, a heat regulation device 1927, and a hardware security device 1928.

Processing device 1901 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1901 may include a memory 1902, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing 1901 shares a package with memory 1902. This memory may be used as cache memory and may include embedded dynamic random-access memory (eDRAM) or spin transfer torque magnetic random-access memory (STT-M RAM).

Computing device 1900 may include a heat regulation/refrigeration device 1923. Heat regulation/refrigeration device 1923 may maintain processing device 1901 (and/or other components of computing device 1900) at a predetermined low temperature during operation. This predetermined low temperature may be any temperature discussed elsewhere herein.

In some embodiments, computing device 1900 may include a communication chip 1907 (e.g., one or more communication chips). For example, the communication chip 1907 may be configured for managing wireless communications for the transfer of data to and from computing device 1900. The term “wireless” and its derivatives may be used to describe circuits, devices, systems, methods, techniques, communications channels, etc., that may communicate data through the use of modulated electromagnetic radiation through a nonsolid medium.

Communication chip 1907 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1907 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1907 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1907 may operate in accordance with other wireless protocols in other embodiments. Computing device 1900 may include an antenna 1913 to facilitate wireless communications and/or to receive other wireless communications (such as AM or FM radio transmissions).

In some embodiments, communication chip 1907 may manage wired communications, such as electrical, optical, or any other suitable communication protocols (e.g., the Ethernet). As noted above, communication chip 1907 may include multiple communication chips. For instance, a first communication chip 1907 may be dedicated to shorter-range wireless communications such as Wi-Fi or Bluetooth, and a second communication chip 1907 may be dedicated to longer-range wireless communications such as GPS, EDGE, GPRS, CDMA, WiMAX, LTE, EV-DO, or others. In some embodiments, a first communication chip 1907 may be dedicated to wireless communications, and a second communication chip 1907 may be dedicated to wired communications.

Computing device 1900 may include battery/power circuitry 1908. Battery/power circuitry 1908 may include one or more energy storage devices (e.g., batteries or capacitors) and/or circuitry for coupling components of computing device 1900 to an energy source separate from computing device 1900 (e.g., AC line power).

Computing device 1900 may include a display device 1903 (or corresponding interface circuitry, as discussed above). Display device 1903 may include any visual indicators, such as a heads-up display, a computer monitor, a projector, a touchscreen display, a liquid crystal display (LCD), a light-emitting diode display, or a flat panel display, for example.

Computing device 1900 may include an audio output device 1904 (or corresponding interface circuitry, as discussed above). Audio output device 1904 may include any device that generates an audible indicator, such as speakers, headsets, or earbuds, for example.

Computing device 1900 may include an audio input device 1910 (or corresponding interface circuitry, as discussed above). Audio input device 1910 may include any device that generates a signal representative of a sound, such as microphones, microphone arrays, or digital instruments (e.g., instruments having a musical instrument digital interface (MIDI) output).

Computing device 1900 may include a global positioning system (GPS) device 1909 (or corresponding interface circuitry, as discussed above). GPS device 1909 may be in communication with a satellite-based system and may receive a location of computing device 1900, as known in the art.

Computing device 1900 may include another output device 1905 (or corresponding interface circuitry, as discussed above). Examples include an audio codec, a video codec, a printer, a wired or wireless transmitter for providing information to other devices, or an additional storage device.

Computing device 1900 may include another input device 1911 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1900 may include a security interface device 1912. Security interface device 1912 may include any device that provides security measures for computing device 1900 such as intrusion detection, biometric validation, security encode or decode, managing access lists, malware detection, or spyware detection.

Computing device 1900, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In a first examples, an apparatus comprises an integrated circuit (IC) die structure of a thickness no more than 50 μm. The IC die structure has a first region comprising one or more first metal features and an inorganic dielectric material, and a second, adjacent, region comprising a material with a composition of at least ten atomic percent carbon or at least ten atomic percent fluorine. The apparatus comprises a substrate in direct contact with at least the first region of the IC die structure, wherein the substrate has a third region comprising one or more second metal features and an inorganic dielectric material, and a fourth, adjacent, region comprising a material with a composition of at least ten atomic percent carbon or at least ten atomic percent fluorine, and wherein the second metal features are in contact with at least a portion of corresponding ones of the first metal features. The apparatus comprises a dielectric material adjacent to an edge of the IC die structure, and over a region of the substrate beyond the edge of the IC die structure, wherein a back side of the IC die structure, opposite the substrate, is substantially co-planar with the dielectric material adjacent to the edge of the IC die structure.

In second examples, for any of the first examples one of the back side of the IC die structure and the dielectric material adjacent to the edge of the IC die is recessed, relative to the other, by a non-zero amount not exceeding 10% of the IC die structure thickness.

In third examples, for any of the first through second examples the apparatus further comprises one or more dielectric material layers over the IC die structure and over the dielectric material adjacent to the edge of the IC die structure. The one or more dielectric material layers planarizing a surface spanning the IC die structure and the dielectric material adjacent to the edge of the IC die structure.

In fourth examples, for any of the first through third examples the IC die structure comprises a silicon layer having a thickness less than 10 μm.

In fifth examples, for any of the first through fourth examples the IC die structure is a first IC die structure, and the substrate comprises a plurality of the third regions. The apparatus further comprises a second IC die structure with a fifth region comprising third metal features and a dielectric material, the fifth region adjacent to a sixth region comprising a material with a composition of at least ten atomic percent carbon or at least ten atomic percent fluorine. The third metal features are in contact with at least a portion of corresponding ones of the second metal features, and wherein a back side of the first IC die structure is substantially coplanar with a back side of the second IC die structure.

In sixth examples, for any of the first through fifth examples the second region is adjacent to two non-parallel edges of the first region, and wherein second fourth region is adjacent to two non-parallel edges of the third region.

In seventh examples, for any of the sixth examples the second region is substantially surrounding a perimeter of the first region, or the fourth region is substantially surrounding a perimeter of the third region.

In eighth examples, for any of the first through seventh examples one or more of the second or fourth regions have greater average surface roughness than an adjacent one of the first or second regions, or wherein one or more of the second or fourth regions comprise a polymer in contact with a sidewall of an adjacent one of the first or second regions.

In ninth examples for any of the first through eighth examples the IC die structure comprises two or more IC die, the two or more IC die substantially coplanar or stacked one upon the other; and the substrate comprises a second side, opposite the IC die structure, the second side comprising one or more solder interconnect features.

In tenth examples, an apparatus comprises an integrated circuit (IC) die structure of a thickness no more than 50 μm. Th IC die structure has a first region comprising one or more first metal features and an inorganic dielectric material, and a second, adjacent, region comprising a layer of material with a composition of at least ten atomic percent carbon or at least ten atomic percent fluorine. The apparatus comprises a substrate in direct contact with at least the first region of the IC die structure. The substrate has a third region comprising one or more second metal features and an inorganic dielectric material, and a fourth, adjacent, region comprising a layer of material with a composition of at least ten atomic percent carbon or at least ten atomic percent fluorine, and the second metal features are in contact with at least a portion of corresponding ones of the first metal features. The apparatus comprises a dielectric material layer adjacent to an edge of the IC die structure and extending over a back side of the IC die structure, opposite the substrate.

In eleventh examples, for any of the tenth examples the continuous dielectric material layer is a first dielectric material layer having first thickness in a direction substantially normal to the back side of the IC die structure and a second thickness in a direction substantially normal to the edge of the IC die structure, and wherein the first thickness is within 10% of the second thickness.

In twelfth examples, for any of the tenth through eleventh examples the dielectric material layer is a first dielectric material layer. The apparatus further comprises one or more second dielectric material layers over the first dielectric material layer. The one or more second dielectric material layers planarize a surface spanning the IC die structure and the first dielectric material adjacent to the edge of the IC die structure.

In thirteenth examples, for any of the eleventh through twelfth examples the IC die structure comprises silicon layer having a thickness less than 10 μm.

In fourteenth examples, for any of the eleventh through thirteenth examples, the IC die structure is a first IC die structure, and the apparatus further comprises a second IC die structure with a fifth region comprising one or more third metal features and a dielectric material. The third metal features are in contact with at least a portion of corresponding ones of the second metal features. A back side of the first IC die structure is non-planar with a back side of the second IC die structure. The dielectric material layer is also adjacent to the edge of the second IC die structure and extends over a back side of the second IC die structure.

In fifteenth examples, for any of the fourteenth examples the dielectric material layer is a first dielectric material layer and further comprising a second dielectric material layer over the continuous dielectric material, the second dielectric material layer substantially planarizing an area spanning both the first IC die structure and the second IC die structure.

In sixteenth examples, a method comprises receiving an integrated circuit (IC) die structure of a first thickness. The IC die structure has a first region comprising one or more first metal features and an inorganic dielectric material, and a second, adjacent, region comprising a layer of material with a composition of at least ten atomic percent carbon or at least ten atomic percent fluorine. The method comprises receiving a substrate with a third region comprising one or more second metal features and an inorganic dielectric material, and a fourth, adjacent, region comprising a layer of material of a composition of at least ten atomic percent carbon or at least ten atomic percent fluorine. The method comprises aligning the IC die structure to the substrate based on a wettability contrast between the first and second regions or a wettability contrast between the third and fourth regions. The method comprises bonding the first region to second region. The bonding comprises contacting the first metal features with at least a portion of corresponding ones of the second metal features. The method comprises reducing the IC die structure to a second thickness after at least one of the aligning or bonding.

In seventeenth examples, for any of the sixteenth examples the method comprises depositing a dielectric material layer adjacent to an edge of the IC die structure and over a portion of the substrate beyond the edge of the IC die structure. Reducing the IC die structure to the second thickness comprises polishing a back side of the IC die structure, opposite the substrate.

In eighteenth examples, for any of the seventeenth examples the polishing comprises recessing a surface of the IC die structure by a first amount and recessing a surface of the dielectric material layer by a second amount that differs from the first amount.

In nineteenth examples, for any of the sixteenth through eighteenth examples the method further comprises depositing a dielectric material over the IC die structure of the second thickness.

In twentieth examples, for any of the sixteenth through nineteenth examples the second thickness is less than half the first thickness.

In twenty-first examples, for any of the sixteenth through twentieth examples the first thickness is over 50 μm and the second thickness is less than 50 μm.

In twenty-second examples, for any of the twenty-first examples the second thickness comprises a layer of silicon less than 10 μm in thickness.

In twenty-third examples, for any of the sixteenth through twenty-second examples the IC die structure is a first IC die structure, the substrate comprises a plurality of the third regions, and the method further comprises receiving a second IC die structure of a third thickness, the second IC die structure having a fourth region comprising third metal features and an inorganic dielectric material, and bonding the second IC die structure to the substrate. The fourth metal features contact at least a portion of corresponding ones of the second metal features, and the method comprises reducing the first IC die structure to the second thickness comprises planarizing a surface of the first IC die structure with a surface of the second IC die structure and reducing the second IC die structure to a fourth thickness.

In twenty-fourth examples, for any of the sixteenth through twenty-third examples reducing the IC die structure to the second thickness comprises removing the carrier from a back side of the IC die structure, opposite the substrate.

In twenty-fifth examples, for any of the twenty-fourth examples removing the carrier comprises transferring the carrier to a host by adhering a second side of the carrier, opposite the IC die structure, to the host.

In twenty-sixth examples, for any of the twenty-fifth examples removing the carrier comprises mechanically delaminating the carrier from the first side of the IC die structure or comprises removing an adhesion layer from between the carrier and the first side of the IC die structure through chemical etching, thermal decomposition, laser ablation, or exposure to UV radiation.

In twenty-seventh examples, for any of the twenty-fourth through twenty-sixth examples the method comprises depositing a dielectric material layer over the back side of the IC die structure and adjacent to an edge of the IC die structure.

In twenty-eighth examples, for any of the twenty-fourth through twenty-seventh examples the IC die structure is a first IC die structure, the substrate comprises a plurality of third regions. The method further comprises receiving a second integrated circuit (IC) die structure, wherein a back side of the second IC die structure is attached to a second carrier and wherein a front side of the second IC die structure comprises a fifth region comprising one or more third metal features and an inorganic dielectric material. The method further comprises bonding the fifth region to a corresponding one of the third regions, wherein the bonding comprises contacting the third metal features with at least a portion of corresponding ones of the second metal features. The method further comprises removing the second carrier from the second side of the second IC die structure.

In twenty-ninth examples, for any of the twenty-eighth examples the method comprises depositing the dielectric material layer over the second side of the second IC die structure and adjacent to an edge of the second IC die structure.

It will be recognized that principles of the disclosure are not limited to the embodiments so described, but instead can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
an integrated circuit (IC) die structure of a thickness no more than 50 μm, wherein the IC die structure has a first region comprising one or more first metal features and an inorganic dielectric material, and a second, adjacent, region comprising a material with a composition of at least ten atomic percent carbon or at least ten atomic percent fluorine;
a substrate in direct contact with at least the first region of the IC die structure, wherein the substrate has a third region comprising one or more second metal features and an inorganic dielectric material, and a fourth, adjacent, region comprising a material with a composition of at least ten atomic percent carbon or at least ten atomic percent fluorine, and wherein the second metal features are in contact with at least a portion of corresponding ones of the first metal features; and
a dielectric material adjacent to an edge of the IC die structure, and over a region of the substrate beyond the edge of the IC die structure, wherein a back side of the IC die structure, opposite the substrate, is substantially co-planar with the dielectric material adjacent to the edge of the IC die structure.

2. The apparatus of claim 1, wherein one of the back side of the IC die structure and the dielectric material adjacent to the edge of the IC die is recessed, relative to the other, by a non-zero amount not exceeding 10% of the IC die structure thickness.

3. The apparatus of claim 1, further comprising one or more dielectric material layers over the IC die structure and over the dielectric material adjacent to the edge of the IC die structure, the one or more dielectric material layers planarizing a surface spanning the IC die structure and the dielectric material adjacent to the edge of the IC die structure.

4. The apparatus of claim 1, wherein the IC die structure comprises a silicon layer having a thickness less than 10 μm.

5. The apparatus of claim 1, wherein the IC die structure is a first IC die structure, and the substrate comprises a plurality of the third regions; and
further comprising a second IC die structure with a fifth region comprising third metal features and a dielectric material, the fifth region adjacent to a sixth region comprising a material with a composition of at least ten atomic percent carbon or at least ten atomic percent fluorine, wherein the third metal features are in contact with at least a portion of corresponding ones of the second metal features, and wherein a back side of the first IC die structure is substantially coplanar with a back side of the second IC die structure.

6. The apparatus of claim 1, wherein the second region is adjacent to two non-parallel edges of the first region, and wherein second fourth region is adjacent to two non-parallel edges of the third region.

7. The apparatus of claim 6, wherein the second region is substantially surrounding a perimeter of the first region, or the fourth region is substantially surrounding a perimeter of the third region.

8. The apparatus of claim 1, wherein one or more of the second or fourth regions have greater average surface roughness than an adjacent one of the first or second regions, or wherein one or more of the second or fourth regions comprise a polymer in contact with a sidewall of an adjacent one of the first or second regions.

9. The apparatus of claim 1, wherein:
the IC die structure comprises two or more IC die, the two or more IC die substantially coplanar or stacked one upon the other; and
the substrate comprises a second side, opposite the IC die structure, the second side comprising one or more solder interconnect features.

10. An apparatus comprising:
an integrated circuit (IC) die structure of a thickness no more than 50 μm, wherein the IC die structure has a first region comprising one or more first metal features and an inorganic dielectric material, and a second, adjacent, region comprising a layer of material with a composition of at least ten atomic percent carbon or at least ten atomic percent fluorine;
a substrate in direct contact with at least the first region of the IC die structure, wherein the substrate has a third region comprising one or more second metal features and an inorganic dielectric material, and a fourth, adjacent, region comprising a layer of material with a composition of at least ten atomic percent carbon or at least ten atomic percent fluorine, and wherein the second metal features are in contact with at least a portion of corresponding ones of the first metal features; and
a dielectric material layer adjacent to an edge of the IC die structure and extending over a back side of the IC die structure, opposite the substrate.

11. The apparatus of claim 10, wherein the continuous dielectric material layer is a first dielectric material layer having first thickness in a direction substantially normal to the back side of the IC die structure and a second thickness in a direction substantially normal to the edge of the IC die structure, and wherein the first thickness is within 10% of the second thickness.

12. The apparatus of claim 11, wherein the dielectric material layer is a first dielectric material layer, and further comprising one or more second dielectric material layers over the first dielectric material layer, wherein the one or more second dielectric material layers planarize a surface spanning the IC die structure and the first dielectric material adjacent to the edge of the IC die structure.

13. The apparatus of claim 11, wherein the IC die structure comprises silicon layer having a thickness less than 10 μm.

14. The apparatus of claim 11, wherein:
the IC die structure is a first IC die structure, and further comprising a second IC die structure with a fifth region comprising one or more third metal features and a dielectric material;
the third metal features are in contact with at least a portion of corresponding ones of the second metal features, wherein a back side of the first IC die structure is non-planar with a back side of the second IC die structure;
the dielectric material layer is also adjacent to the edge of the second IC die structure and extends over a back side of the second IC die structure.

15. The apparatus of claim 14, wherein the dielectric material layer is a first dielectric material layer and further comprising a second dielectric material layer over the continuous dielectric material, the second dielectric material layer substantially planarizing an area spanning both the first IC die structure and the second IC die structure.

16. A method, comprising:
receiving an integrated circuit (IC) die structure of a first thickness, wherein the IC die structure has a first region comprising one or more first metal features and an inorganic dielectric material, and a second, adjacent, region comprising a layer of material with a composition of at least ten atomic percent carbon or at least ten atomic percent fluorine;
receiving a substrate with a third region comprising one or more second metal features and an inorganic dielectric material, and a fourth, adjacent, region comprising a layer of material of a composition of at least ten atomic percent carbon or at least ten atomic percent fluorine;
aligning the IC die structure to the substrate based on a wettability contrast between the first and second regions or a wettability contrast between the third and fourth regions;
bonding the first region to second region, wherein the bonding comprises contacting the first metal features with at least a portion of corresponding ones of the second metal features; and
reducing the IC die structure to a second thickness after at least one of the aligning or bonding.

17. The method of claim 16, further comprising depositing a dielectric material layer adjacent to an edge of the IC die structure and over a portion of the substrate beyond the edge of the IC die structure, and wherein reducing the IC die structure to the second thickness comprises polishing a back side of the IC die structure, opposite the substrate.

18. The method of claim 17, wherein the polishing comprises recessing a surface of the IC die structure by a first amount and recessing a surface of the dielectric material layer by a second amount that differs from the first amount.

19. The method of claim 16, wherein the method further comprises depositing a dielectric material over the IC die structure of the second thickness.

20. The method of claim 16, wherein the second thickness is less than half the first thickness.
